(19) United States
(12) Patent Application Publication
(10) Pub. No.: US 2020/0355727 A1
(43) Pub. Date: Nov. 12, 2020

(54) APPARATUS FOR CHECKING PIN CONTACT PRESSURE USING Z-AXIAL FEEDER OF FLAT PANEL DISPLAY INSPECTION DEVICE

(71) Applicant: Yang Yoon Seon, Seoul (KR)

(72) Inventor: Yang Yoon Seon, Seoul (KR)

(21) Appl. No.: 16/406,481

(22) Filed: May 8, 2019

(51) Int. Cl. G01R 1/067

(52) U.S. Cl. CPC G01R 1/06794

(57) ABSTRACT

The present disclosure relates to an apparatus for checking pin contact pressure using a z-axial feeder of a flat panel display inspection device. The present disclosure provides an apparatus for checking pin contact pressure using a z-axial feeder of a flat panel display inspection device, the apparatus being able to minimize an error and pressure in contact by vertically sliding contact pins of a probe card without friction using frictionless vertical moving members when the top of a flat panel display and the contact pins of the probe card come in contact with each other in a flat panel display inspection process.

### BACKGROUND OF THE INVENTION

### 1. Field of the Invention

The present disclosure relates to an apparatus for checking pin contact pressure using a z-axial feeder of a flat panel display inspection device. More particularly, the present disclosure relates to n apparatus for checking pin contact pressure using a z-axial feeder of a flat panel display inspection device the apparatus physically bringing a probe pin in contact with a pattern at a desired position and then transmitting data to tester equipment to inspect the data by driving a feeder with a flat panel display fixed on a state in an inspection process that is the final process of manufacturing a flat panel display product.

### 2. Description of Related Art

In general, a flat panel display includes a Liquid Crystal Display (LCD), a Plasma Display Panel (PDP), and a Field Emission Display (FED).

A process of manufacturing a bottom substrate, a process of manufacturing a top substrate, a process of bonding the bottom substrate and the top substrate etc. are performed to manufacture such flat panel displays.

In detail, a plurality of cells are formed on a glass disc for manufacturing a bottom substrate, a plurality of horizontal lines and vertical lines are formed across each other in a matrix shape on the cells, and pixel cells including transparent pixel electrodes are formed at the intersections of the horizontal lines and the vertical lines.

Thin film transistors connected to the horizontal lines, the vertical lines, and the pixel electrodes are formed on the pixel cells.

The cells formed on the glass disc are cut in a scribing process after an inspection process, the cells cut from the glass disc, that is, the bottom substrates are respectively bonded to top substrates formed in a process of manufacturing the top substrates, and then a driving circuit and several elements for driving the pixel cells are combined, whereby a flat panel display is accomplished.

When a flat panel display is tested in the process of manufacturing a flat panel display described above, a probing device is moved up and down and a side camera is used to accurately and safely bring a pin in contact in the related art, as shown in FIG. 1.

That is, a probing device 4 is put over a dummy flat panel display area 6, and then the distance between a probe card pin 1 and a flat panel display contact surface 6 is calculated by a side camera 3 and pin contact is attempted by moving up and down the probing device 4 on the basis of the calculated value.

After pin contact is finished, a process of checking whether the probe card pin 1 has been successfully brought in contact with the flat panel display using an upper camera 2 disposed on the probing device 4 is performed, and then a worker performs re-contacting by adjusting a pin contact pressure value through an override adjuster 5.

A condition for safest pin contact is finally set by repeating this process and then pin contact with a test flat panel display is performed, thereby performing pattern inspection on the flat panel display.

In pattern inspection on a flat panel display described above, inspection should be constantly performed with an accurate measurement point and a fine contact depth maintained. However, setting an override value unavoidably depends on a skillful worker in inspection of a flat panel display according to methods of the related art. Further, flat panel displays to be inspected are uneven, so it is difficult to set an override value every time. Further, even though setting is finished, shock is applied to a probe card pin and the setting time is long.

### SUMMARY OF THE INVENTION

The present disclosure has been made in order to solve the above-mentioned problems in the prior art and an aspect of the present disclosure is to provide an apparatus for checking pin contact pressure using a z-axial feeder of a flat panel display inspection device, the apparatus being able to vertically slide contact pins of a probe card without friction using frictionless vertical moving members when the top of a flat panel display and the contact pins of the probe card come in contact with each other in a flat panel display inspection process.

That is, the present disclosure provides an apparatus for checking pin contact pressure using a z-axial feeder of a flat panel display inspection device, the apparatus being able to minimize an error and pressure in contact by vertically moving a contact pin of a probe card without friction in a flat panel display inspection process.

Another aspect of the present disclosure is to provide an apparatus for checking pin contact pressure using a z-axial feeder of a flat panel display inspection device, the apparatus being able to provide more precise pin contact by measuring pressure in contact of contact pins of a probe card in a flat panel display inspection device and then checking and adjusting in real time an override setting value at a predetermined level on the basis of the pressure.

In accordance with an aspect of the present disclosure, there is provided an apparatus for checking pin contact pressure using a z-axial feeder of a flat panel inspection device, the apparatus being configured to selectively come in contact with the top of a flat panel display placed on a stage by operating through a vertical moving unit configured to operate with a predetermined driving unit applying z-axial external force, and the apparatus including: guide blocks fixed to the vertical moving unit to vertically move together; a moving block installed to vertically move along the guide blocks; frictionless vertical moving members inserted in the guide blocks and disposed at sides of the moving block such that the moving block is moved without friction by compressed air that is injected from the outside; a probing unit having a probe card that comes in contact with the top of the flat panel display to be inspected, and integrally disposed on a lower portion of the moving block; a pin contact check sensor measuring contact pressure of contact pins and generating a signal corresponding to the contact pressure when the moving block is moved up by contact pin pressure of the probe card; and compression springs applying external force for returning the moving block that has been moved up when the vertical moving unit that has been moved down returns.

According to the present disclosure, as described above, since it is possible to vertically slide the contact pins of the probe card without friction through the frictionless vertical moving members when the contact pins and the top of a flat panel display come in contact with each other in an inspection process of the flat panel display, it is possible to minimize an error in contact with the probe contact pins, so it is possible to more precisely bring the probe card contact pins in contact with the top of the flat panel display.

Therefore, it is possible to provide a more accurate measurement result and consistency when inspecting a flat panel display and to achieve equipment having more excellent performance. Further, it is possible to improve test precision and obtain data with high reliability .

### BRIEF DESCRIPTION OF THE DRAWINGS

The features of the invention believed to be novel and the elements characteristic of the invention are set forth with particularity in the appended claims. The figures are for illustration purposes only and are not drawn to scale. The above and other aspects, features and advantages of the present disclosure will be more apparent from the following detailed description taken in conjunction with the accompanying drawings, in which:

FIG. 1 is a view showing a schematic configuration of a flat panel display inspection device of the related art;

FIG. 2 is a perspective view showing the external appearance of an apparatus for checking pin contact pressure using a z-axial feeder of a flat panel display inspection device according to the present disclosure;

FIG. 3 is a perspective view showing the configuration of the apparatus for checking pin contact pressure using a z-axial feeder of a flat panel display inspection device according to the present disclosure;

FIG. 4 is an exploded perspective view showing the configuration of the apparatus for checking pin contact pressure using a z-axial feeder of a flat panel display inspection device according to the present disclosure;

FIGS. 5A to 5C are front views showing a process of inspecting a flat panel display using the apparatus for checking pin contact pressure using a z-axial feeder of a flat panel display inspection device according to the present disclosure; and

FIG. 6 is a view showing the operation state of a pin contact check sensor installed in the apparatus for checking pin contact pressure using a z-axial feeder of a flat panel display inspection device according to the present disclosure.

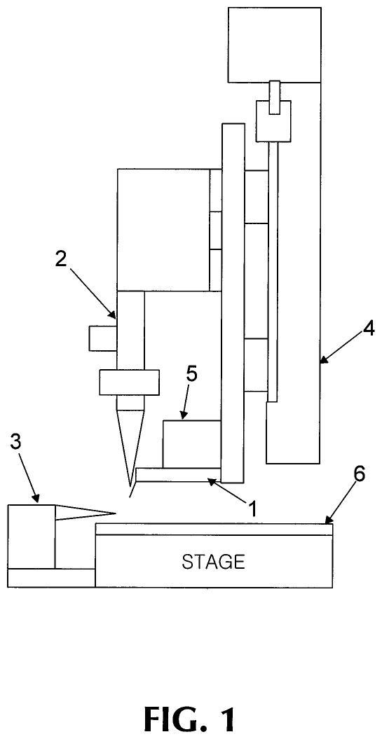

### DETAILED DESCRIPTION OF THE EXEMPLARY EMBODIMENTS

Hereinafter, the present disclosure having the configuration described above will be described in detail with reference to the accompanying drawings.

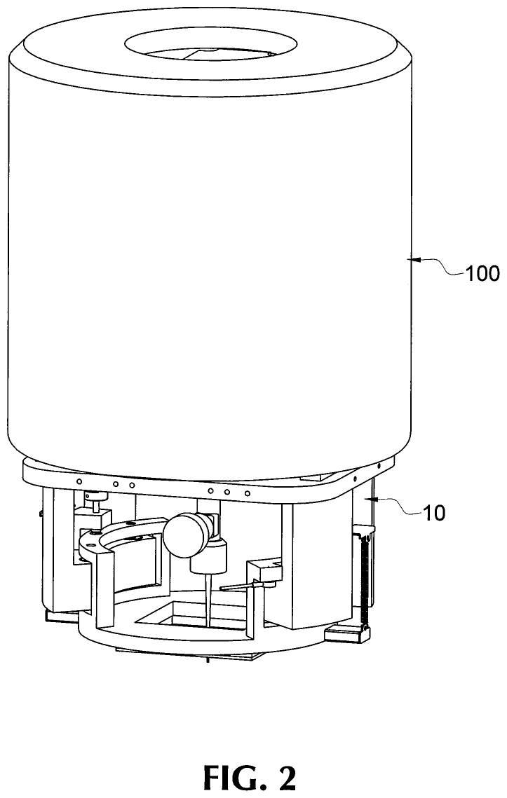

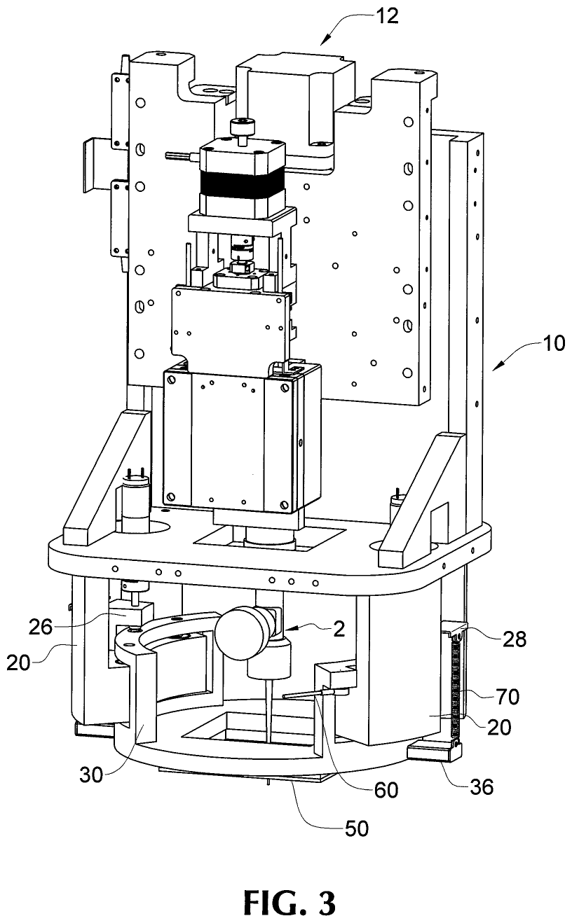

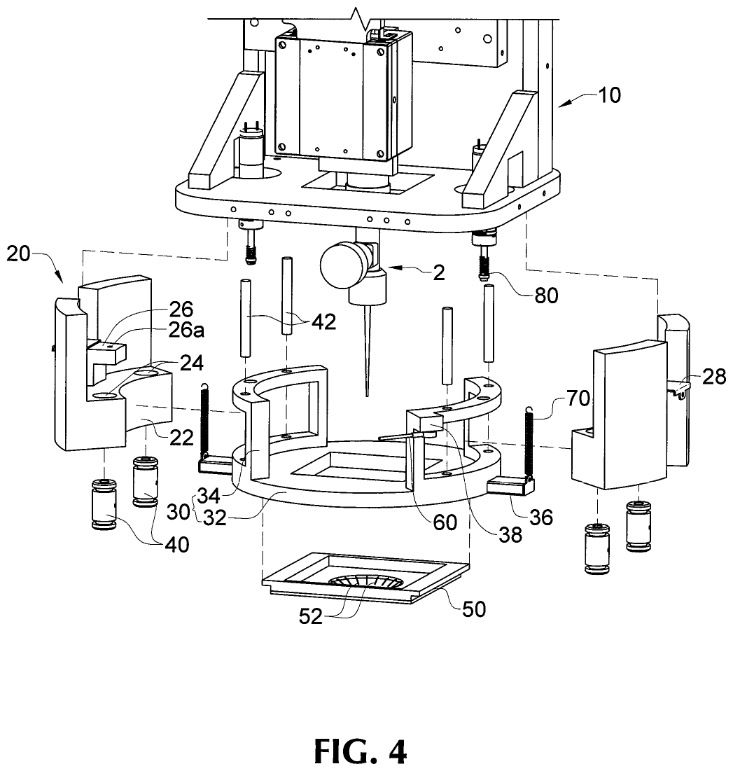

FIG. 2 is a perspective view showing the external appearance of an apparatus for checking pin contact pressure using a z-axial feeder of a flat panel display inspection device according to the present disclosure, FIG. 3 is a perspective view showing the configuration of the apparatus for checking pin contact pressure using a z-axial feeder of a flat panel display inspection device according to the present disclosure, and FIG. 4 is an exploded perspective view showing the configuration of the apparatus for checking pin contact pressure using a z-axial feeder of a flat panel display inspection device according to the present disclosure.

First, an apparatus for checking pin contact pressure using a z-axial feeder of a flat panel display inspection device according to the present disclosure is configured to be able to vertically slide a contact pin 52 of a probe card 50 without friction using frictionless vertical moving members 40 when the top of a flat panel display 6 and the contact pin 52 come in contact with each other in a pattern inspection process of the flat panel display 6 using a flat panel display inspection device.

To this end, in the apparatus for checking pin contact pressure using a z-axial feeder of a flat panel display inspection device according to the present disclosure, the contact pin 52 of the probe card 50 that is selectively brought in contact with the top of the flat panel display 6 by a predetermined driving unit is installed to be vertically movable with friction removed.

The driving unit includes a driving motor 12 that provides vertical driving force, and a vertical moving unit 10 that is a predetermined structure being able to operate with the driving unit is installed on the driving unit to be selectively vertically moved by the driving force from the driving motor 12. Accordingly, when the vertical moving unit 10 is vertically moved, the contact pin 52 of the probe card 50 is selectively brought in contact with the surface of the flat panel display 6 on a stage by guide blocks 20, a moving block 30, and frictionless vertical moving members 40.

The guide blocks 20 are a pair of blocks respectively fixed to two sides of the bottom of the vertical moving unit 10, have a “(”-shaped or “)”-shaped plane, and have extensions 22 protruding toward the inner sides at the lower portions. A pair of installation holes 24 may be vertically formed through each of the extensions 22 of the guide blocks 20 such that the frictionless vertical moving members 40 are installed therein.

Stoppers 26 for limiting the position of the moving block 30 moving up are disposed on the tops of the extensions 22 of the guide blocks 20 and have a substantially “┌”-shaped or “┐”-shaped front, and through-holes 26a are formed in the ceiling portions of the stoppers such that lower ends of automatic override adjusters 80 pass through the through-holes 26a.

The moving block 30 can be vertically moved and guided by the guide blocks 20 combined with the frictionless vertical moving members 40 and has a base 32 having a substantially disc shape, in which a pair of vertical portions 34 having substantially rectangular frame shapes and having a “(”-shaped or “)”-shaped plane are integrally formed at both edges of the top of the base 32.

The extensions 22 of the guide blocks 20 are inserted inside the vertical portions 34 of the moving block 30 with a predetermined gap therebetween and guide shafts 42 are vertically installed in the vertical portions 34 through the frictionless vertical moving members 40 inserted in the extensions 22.

The frictionless vertical moving members 40 are operated to perform the same function as a bearing without friction by compressed air that is injected from the outside so that the moving block 30 can be smoothly moved up and down on the guide shafts 42.

The probe card 50 is disposed at the center of the base 32 of the moving block 30 to vertically move with the moving block 30 when the vertical moving unit 10 is moved, and has contact pins 52 at the center that come in contact with a flat panel display 6 placed on the stage of the inspection device.

A contact protrusion 38 is formed at one of the vertical portions 34 of the moving block 30 and a pin contact check sensor 60 fixed at a predetermined position on the apparatus is disposed in contact with the contact protrusion 38, thereby measuring pressure that is applied to the contact pins 52 when the moving block 30 is moved up and returned by physical contact of the contact pins 52 of the probe card 50 and the flat panel display 6, and generating an electrical signal based on the pressure.

Reference numeral ‘70’ indicates compression springs, which are respectively fixed at both ends to spring installation protrusions 28 and 36 of the guide blocks 20 and the moving block 30 to maintain initial position values by applying external force such that the moving block 30 moved up by physical contact pressure of the contact pins 52 of the probe card 50 can be returned to the initial position when the guide blocks 20 moved down a predetermined distance by the vertical moving unit 10 is moved up.

A pair of automatic override adjusters 80 are installed on the vertical moving unit 10 with ends in contact with the top of the moving block 30. When a pressure value detected by the pin contact check sensor 60 is converted into an electrical signal and input in real time, the automatic override adjusters 80 can automatically control override of the probe card contact pins 52 on the basis of the information.

Reference numeral ‘2’ indicates a camera provided to check the state when the probe card contact pins 52 come in contact with the flat panel display 6 and reference numeral ‘100’ indicates a housing in which the vertical moving unit including the driving motor 12 is disposed.

The operation of the present disclosure having the configuration described above is described in detail hereafter.

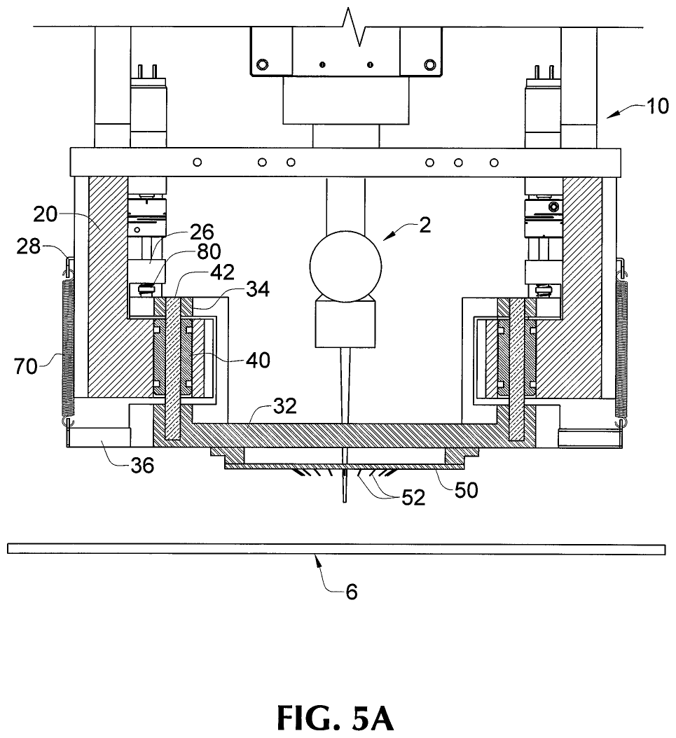

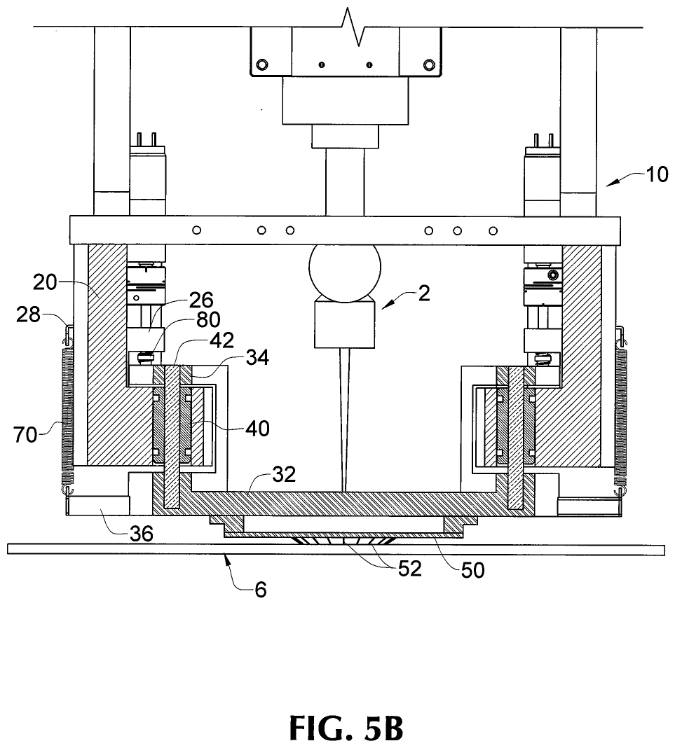

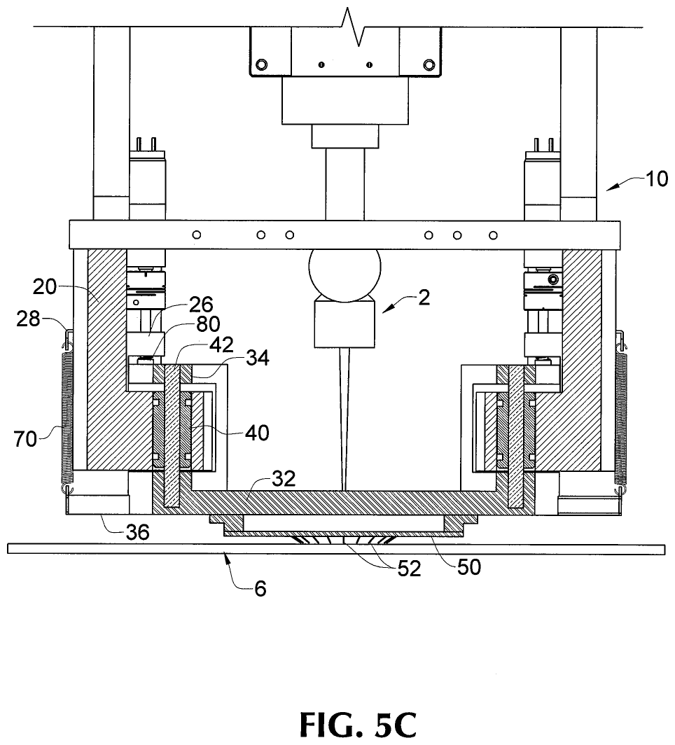

First, in a process of testing a predetermined flat panel display 6 using a probe inspection device equipped with the apparatus for checking pin contact pressure using a z-axial feeder, a probing unit including the probe card 50 disposed on the probe inspection device is moved to a test position over the flat panel display 6 and then the driving motor 12 for feeding the probe card 50 in the z-axial direction is operated, thereby moving down the vertical moving unit 10 a predetermined distance (see FIG. 5A).

As the vertical moving unit 10 is moved down, the guide blocks 20 and the moving block 30 configured to operate with the vertical moving unit 10 are also integrally moved down. Further, the contact pins 52 of the probe card 50 disposed at the center of the base 32 of the moving block 30 come in contact with the top of the flat pane display 6 (see FIG. 5B).

When the contact pins 52 of the probe card 50 come in contact with the top of the flat panel display 6, the moving block 30 configured to operate with the contact pins 52 of the probe card 50 is moved up along the frictionless vertical moving members 40 by the contact pressure. In this process, the moving block 30 can be smoothly moved up without friction along the guide shafts 42 inserted through the frictionless vertical moving members 40 by compressed air that is injected to the frictionless vertical moving members 40.

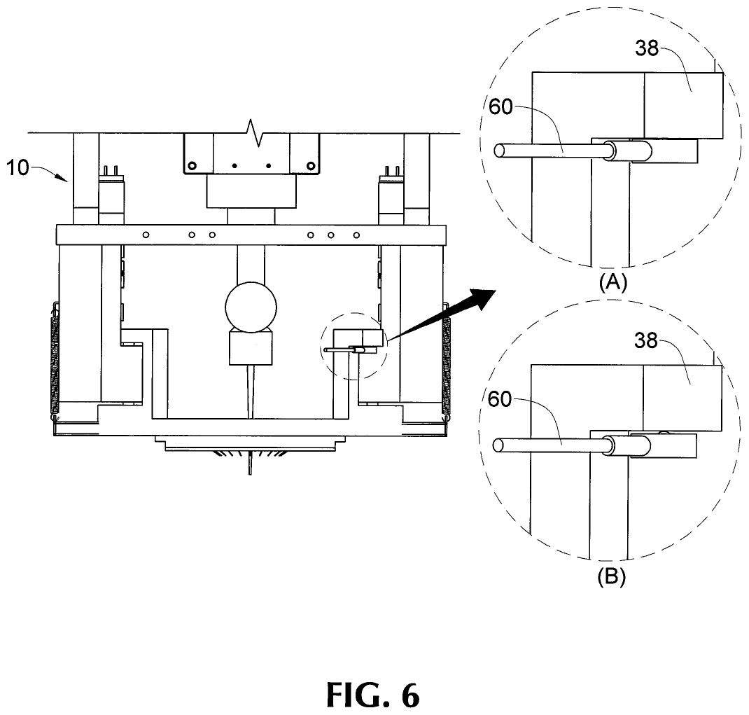

The pin contact check sensor 60 that generates an electrical signal by measuring force by physical contact of the moving block 30 measures an input value ((A)==>(B) in FIG. 6) that changes with moving-up of the moving block 30 and generates a signal. When the signal comes out of a predetermined reference value that is an override setting value, the driving motor 12 is controlled to stop and a predetermined inspection process can be performed by the camera 2 etc. on signal wires and pixel electrodes of the flat panel display 6 in accordance with a predetermined test signal (see FIG. 5C).

After the predetermined inspection process is finished, when the vertical moving unit 10 that operates the guide blocks 20 is moved up by operating the driving motor 12, the moving block 30 moved up at a predetermined height is moved down and returned to the initial position by restoring force of the compression springs 70.

In this process, the moving block 30 physically comes in contact with the automatic override adjusters 80, the force generated by the physical contact is measured by the pin contact check sensor 60, and when the force reaches a predetermined pressure reference value, the apparatus enters a standby state.

When the moving block 30 that is returning is not returned with the predetermined pressure value, the automatic override adjusters 80 automatically adjust override of the moving block 30 on the basis of a pressure value that is transmitted in real time through the pin contact check sensor 60.

Although exemplary embodiments of the present disclosure are illustrated and described above, the present disclosure is not limited to the specific exemplary embodiments and may be modified and changed in various ways by those skilled in the art without departing from the scope of the present disclosure described in claims, and the modified and changed examples should not be construed independently from the spirit of the scope of the present disclosure.

Thus, having described the invention, what is claimed is:

1. An apparatus for checking pin contact pressure using a z-axial feeder of a flat panel inspection device, the apparatus being configured to selectively come in contact with the top of a flat panel display placed on a stage by operating through a vertical moving unit configured to operate with a predetermined driving unit applying z-axial external force, the apparatus comprising:
guide blocks fixed to the vertical moving unit to vertically move together;
a moving block installed to vertically move along the guide blocks;
frictionless vertical moving members inserted in the guide blocks and disposed at sides of the moving block such that the moving block is moved without friction by compressed air that is injected from the outside;
a probing unit having a probe card that comes in contact with the top of the flat panel display to be inspected, and integrally disposed on a lower portion of the moving block;
a pin contact check sensor measuring contact pressure of contact pins and generating a signal corresponding to the contact pressure when the moving block is moved up by contact pin pressure of the probe card; and
compression springs applying external force for returning the moving block that has been moved up when the vertical moving unit that has been moved down returns.

2. The apparatus of claim 1, wherein automatic override adjusters that control override on the basis of a pressure value detected by the pin contact check sensor are disposed over the moving block.

3. The apparatus of claim 1, wherein the moving block has a disc-shaped base and a pair of vertical portions erected in substantially rectangular frame shapes along both edges of the top of the base, and a pair of guide shafts passing through the frictionless vertical moving members are disposed in each of the vertical portions.

4. The apparatus of claim 1, wherein the compression springs are provided as a pair, and upper ends of the compression springs are fixed to spring installation protrusions of the guide blocks and lower ends of the compression springs are fixed to spring installation protrusions formed on the base of the moving block.

5. The apparatus of claim 1, wherein stoppers for limiting an upward position of the moving block are formed at predetermined positions of the guide blocks over the vertical portions of the moving block.
